(19) United States
(12) Patent Application Publication
(10) Pub. No.: US 2018/0277176 A1
(43) Pub. Date: Sep. 27, 2018

(54) MEMORY SYSTEM AND OPERATING METHOD THEREOF

(71) Applicant: SK hynix Inc., Gyeonggi-do (KR)

(72) Inventor: Sok-Kyu LEE, Gyeonggi-do (KR)

(21) Appl. No.: 15/795,453

(22) Filed: Oct. 27, 2017

(30) Foreign Application Priority Data
Mar. 27, 2017 (KR) 10-2017-0038271

(51) Int. Cl. G11C 7/10; G06F 13/16; G11C 8/06; G06F 12/06

(52) U.S. Cl. CPC G11C 7/1015; G06F 12/0623; G11C 8/06; G06F 13/1673

(57) ABSTRACT

A memory system includes: a memory device; and a controller suitable for controlling the memory device to perform a serial read operation by providing a serial read command and a start physical address for the serial read command when an external read command includes a request for the serial read operation, the serial read command includes consecutive physical address numbers information, in response to the serial read command, the memory device sets a read bias, reads data stored therein with the set read bias according to the start physical address and the consecutive physical address numbers information, and then discharges the read bias.

### CROSS-REFERENCE TO RELATED APPLICATIONS

The present application claims priority of Korean Patent Application No. 10-2017-0038271, filed on Mar. 27, 2017, which is incorporated herein by reference in its entirety.

### BACKGROUND

### 1. Field

Exemplary embodiments of the present invention relate to a memory system and a method for operating the memory system.

### 2. Description of the Related Art

The computer environment paradigm has changed to ubiquitous computing systems that can be used anytime and anywhere. Due to this, use of portable electronic devices such as mobile phones, digital cameras, and notebook computers has rapidly increased. These portable electronic devices generally use a memory system having one or more memory devices for storing data. A memory system may be used as a main or an auxiliary storage device of a portable electronic device.

Memory systems provide excellent stability, durability, high information access speed, and low power consumption because they have no moving parts. Examples of memory systems having such advantages include universal serial bus (USB) memory devices, memory cards having various interfaces, and solid state drives (SSD).

### SUMMARY

Embodiments of the present invention are directed to a memory system capable of reading data more efficiently when the data stored in physically consecutive space are requested to be read, and a method for operating the memory system.

In accordance with an embodiment of the present invention, a memory system may include: a memory device; and a controller suitable for controlling the memory device to perform a serial read operation by providing a serial read command and a start physical address for the serial read command when an external read command includes a request for the serial read operation. The serial read command may include consecutive physical address numbers information. In response to the serial read command, the memory device may set a read bias, may read data stored therein with the set read bias according to the start physical address and the consecutive physical address numbers information, and then may discharge the read bias.

The controller may further determine whether or not the external read command includes the request for the serial read operation by converting the external read command into a plurality of internal read commands each for indicating a read operation performed by a unit of a page, and by determining whether physical addresses corresponding to the internal read commands are consecutive, and a number of the internal read commands may be greater than 3.

When the physical addresses corresponding to the internal read commands are determined as consecutive, the controller may further select as the start physical address a beginning one among the consecutive physical addresses.

The consecutive physical address numbers information may be information of a number of the consecutive physical addresses.

The memory device may include: an address counter suitable for generating subsequent serial addresses and an end physical address based on the start physical address and the consecutive physical address numbers information; and a read operator suitable for setting a read bias level, reading data of the start physical address, the subsequent serial address and the end physical address of the memory device with the set read bias level, and then discharging the set read bias level.

In accordance with another embodiment of the present invention, a method for operating a memory system provided with a memory device and a controller, the method may include: controlling, by the controller, the memory device to perform the serial read operation by providing a serial read command and a start physical address for the serial read command, wherein the serial read command includes consecutive physical address numbers information when an external read command includes a request for a serial read operation; setting, by the memory device, a read bias in response to the serial read command; reading, by the memory device, data stored therein with the set read bias according to the start physical address and the consecutive physical address numbers information; and discharging, by the memory device, the read bias.

The method may further include determining whether or not the external read command includes the request for the serial read operation includes converting the external read command into a plurality of internal read commands each for indicating a read operation performed by a unit of a page, and determining physical addresses corresponding to the internal read commands are consecutive, a number of the internal read commands may be greater than 3.

The method may further include, by the controller when the physical addresses corresponding to the internal read commands are determined as consecutive, selecting as the start physical address a beginning one among the consecutive physical addresses.

The consecutive physical address numbers information may be information of a number of the consecutive physical addresses.

The reading of the data may include: generating subsequent serial addresses and an end physical address based on the start physical address and the consecutive physical address numbers information; and reading data of the start physical address, the subsequent serial address and the end physical address of the memory device with the set read bias level.

### BRIEF DESCRIPTION OF THE DRAWINGS

These and other features and advantages of the present invention will become apparent to those skilled in the art to which the present invention pertains from the following detailed description in reference to the accompanying drawings, wherein:

FIG. 1 is a block diagram illustrating a data processing system including a memory system in accordance with an embodiment of the present invention;

FIG. 2 is a schematic diagram illustrating an exemplary configuration of a memory device employed in the memory system shown in FIG. 1;

FIG. 3 is a circuit diagram illustrating an exemplary configuration of a memory cell array of a memory block in the memory device shown in FIG. 2;

FIG. 4 is a schematic diagram illustrating an exemplary three-dimensional structure of the memory device shown in FIG. 2;

FIG. 5 illustrates further aspects of the memory system of FIG. 1, in accordance with an embodiment of the present invention;

FIG. 6 illustrates an operation of the memory system of FIG. 6, in accordance with an embodiment of the present invention;

FIGS. 7 and 8 illustrate an additional operation in the memory system, in accordance with the embodiment of the present invention shown in FIG. 5; and

FIGS. 9 to 17 are diagrams schematically illustrating application examples of the data processing system shown in FIG. 1 in accordance with various embodiments of the present invention.

### DETAILED DESCRIPTION

Various embodiments of the present invention are described below in more detail with reference to the accompanying drawings. We note, however, that the present invention may be embodied in different other embodiments, forms and variations thereof and should not be construed as being limited to the embodiments set forth herein. Rather, the described embodiments are provided so that this disclosure will be thorough and complete, and will fully convey the present invention to those skilled in the art to which this invention pertains. Throughout the disclosure, like reference numerals refer to like parts throughout the various figures and embodiments of the present invention.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

The drawings are not necessarily to scale and, in some instances, proportions may have been exaggerated in order to dearly illustrate features of the embodiments.

It will be further understood that when an element is referred to as being “connected to”, or “coupled to” another element, it may be directly on, connected to, or coupled to the other element, or one or more intervening elements may be present. In addition, it will also be understood that when an element is referred to as being “between” two elements, it may be the only element between the two elements, or one or more intervening elements may also be present.

The terminology used herein is for the purpose of describing particular embodiments only and is not intended to be limiting of the present invention. As used herein, singular forms are intended to include the plural forms as well, unless the context dearly indicates otherwise. It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

Unless otherwise defined, all terms including technical and scientific terms used herein have the same meaning as commonly understood by one of ordinary skill in the art to which the present invention belongs in view of the present disclosure. It will be further understood that terms, such as those defined in commonly used dictionaries, should be interpreted as having a meaning that is consistent with their meaning in the context of the present disclosure and the relevant art and will not be interpreted in an idealized or overly formal sense unless expressly so defined herein.

In the following description, numerous specific details are set forth in order to provide a thorough understanding of the present invention. The present invention may be practiced without some or all of these specific details. In other instances, well-known process structures and/or processes have not been described in detail in order not to unnecessarily obscure the present invention.

It is also noted, that in some instances, as would be apparent to those skilled in the relevant art, a feature or element described in connection with one embodiment may be used singly or in combination with other features or elements of another embodiment, unless otherwise specifically indicated.

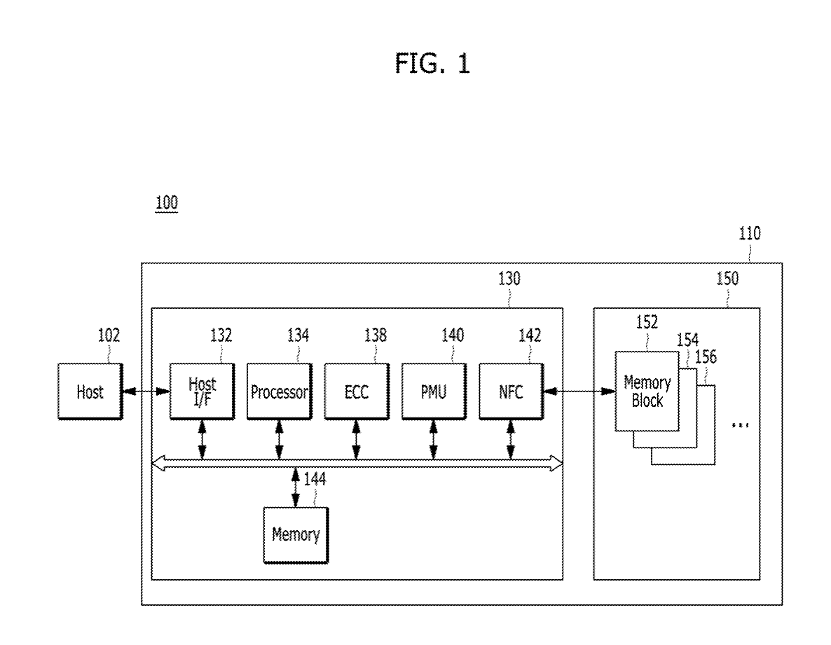

FIG. 1 is a block diagram illustrating a data processing system 100 including a memory system 110 in accordance with an embodiment of the present invention.

Referring to FIG. 1, the data processing system 100 may include a host 102 operatively coupled to the memory system 110.

A suitable host 102 may include a portable electronic device such as a mobile phone, MP3 player and laptop computer or a non-portable electronic device such as a desktop computer, game machine, TV and projector.

The memory system 110 may operate to store data for the host 102 in response to a request of the host 102. Non-limited examples of the memory system 110 may include a solid state drive (SSD), a multi-media card (MMC), a secure digital (SD) card, a universal storage bus (USB) device, a universal flash storage (UFS) device, compact flash (CF) card, a smart media card (SMC), a personal computer memory card international association (PCMCIA) card and memory stick. The MMC may include an embedded MMC (eMMC), reduced size MMC (RS-MMC) and micro-MMC. The SD card may include a mini-SD card and micro-SD card.

The memory system 110 may be embodied by various types of storage devices. Non-limited examples of storage devices included in the memory system 110 may include volatile memory devices such as a DRAM dynamic random access memory (DRAM) and a static RAM (SRAM) and nonvolatile memory devices such as a read only memory (ROM), a mask ROM (MROM), a programmable ROM (PROM), an erasable programmable ROM (EPROM), an electrically erasable programmable ROM (EEPROM), a ferroelectric RAM (FRAM), a phase-change RAM (PRAM), a magneto-resistive RAM (MRAM), resistive RAM (MRAM) resistive RAM (RRAM) and a flash memory. The flash memory may have a 3-dimensional (3D) stack structure.

The memory system 110 may include a memory device 150 and a controller 130. The memory device 150 may store data for the host 120, and the controller 130 may control data storage into the memory device 150.

The controller 130 and the memory device 150 may be integrated into a single semiconductor device, which may be included in the various types of memory systems as exemplified above.

Non-limited application examples of the memory system 110 may include a computer, an Ultra Mobile PC (UMPC), a workstation, a net-book, a Personal Digital Assistant (PDA), a portable computer, a web tablet, a tablet computer, a wireless phone, a mobile phone, a smart phone, an e-book, a Portable Multimedia Player (PMP), a portable game machine, a navigation system, a black box, a digital camera, a Digital Multimedia Broadcasting (DMB) player, a 3-dimensional television, a smart television, a digital audio recorder, a digital audio player, a digital picture recorder, a digital picture player, a digital video recorder, a digital video player, a storage device constituting a data center, a device capable of transmitting/receiving information in a wireless environment, one of various electronic devices constituting a home network, one of various electronic devices constituting a computer network, one of various electronic devices constituting a telematics network, a Radio Frequency Identification (RFID) device, or one of various components constituting a computing system.

The memory device 150 may be a nonvolatile memory device and may retain data stored therein even though power is not supplied. The memory device 150 may store data provided from the host 102 through a write operation, and provide data stored therein to the host 102 through a read operation. The memory device 150 may include a plurality of memory dies (not shown), each memory die including a plurality of planes (not shown), each plane including a plurality of memory blocks 152 to 156, each of the memory blocks 152 to 156 may include a plurality of pages, and each of the pages may include a plurality of memory cells coupled to a word line.

The controller 130 may control the memory device 150 in response to a request from the host 102. For example, the controller 130 may provide data read from the memory device 150 to the host 102, and store data provided from the host. 102 into the memory device 150. For this operation, the controller 130 may control read, write, program and erase operations of the memory device 150.

The controller 130 may include a host interface (I/F) unit 132, a processor 134, an error correction code (ECC) unit 138, a Power Management Unit (PMU) 140, a NAND flash controller (NFC) 142 and a memory 144 all operatively coupled via an internal bus.

The host interface unit 132 may be configured to process a command and data of the host 102, and may communicate with the host 102 through one or more of various interface protocols such as universal serial bus (USB), multi-media card (MMC), peripheral component interconnect-express (PCI-E), small computer system interface (SCSI), serial-attached SCSI (SAS), serial advanced technology attachment (SATA), parallel advanced technology attachment (PATA), enhanced small disk interface (ESDI) and integrated drive electronics (IDE).

The ECC unit 138 may detect and correct an error contained in the data read from the memory device 150. In other words, the ECC unit 138 may perform an error correction decoding process to the data read from the memory device 150 through an ECC code used during an ECC encoding process. According to a result of the error correction decoding process, the ECC unit 138 may output a signal, for example, an error correction success/fail signal. When the number of error bits is more than a threshold value of correctable error bits, the ECC unit 138 may not correct the error bits, and may output an error correction fail signal.

The ECC unit 138 may perform error correction through a coded modulation such as Low Density Parity Check (LDPC) code, Bose-Chaudhri-Hocquenghem (BCH) code, turbo code, Reed-Solomon code, convolution code, Recursive Systematic Code (RSC), Trellis-Coded Modulation (TCM) and Block coded modulation (BCM). However, the ECC unit 138 is not limited thereto. The ECC unit 138 may include all circuits, modules, systems or devices for error correction.

The PMU 140 may provide and manage power of the controller 130.

The NFC 142 may serve as a memory/storage interface for interfacing the controller 130 and the memory device 150 such that the controller 130 controls the memory device 150 in response to a request from the host 102. When the memory device 150 is a flash memory or specifically a NAND flash memory, the NFC 142 may generate a control signal for the memory device 150 and process data to be provided to the memory device 150 under the control of the processor 134. The NFC 142 may work as an interface (e.g., a NAND flash interface) for processing a command and data between the controller 130 and the memory device 150. Specifically, the NFC 142 may support data transfer between the controller 130 and the memory device 150.

The memory 144 may serve as a working memory of the memory system 110 and the controller 130, and store data for driving the memory system 110 and the controller 130. The controller 130 may control the memory device 150 to perform read, write, program and erase operations in response to a request from the host 102. The controller 130 may provide data read from the memory device 150 to the host 102, may store data provided from the host 102 into the memory device 150. The memory 144 may store data required for the controller 130 and the memory device 150 to perform these operations.

The memory 144 may be embodied by a volatile memory. For example, the memory 144 may be embodied by static random access memory (SRAM) or dynamic random access memory (DRAM). The memory 144 may be disposed within or out of the controller 130. FIG. 1 exemplifies the memory 144 disposed within the controller 130. In an embodiment, the memory 144 may be embodied by an external volatile memory having a memory interface transferring data between the memory 144 and the controller 130.

The processor 134 may control the overall operations of the memory system 110. The processor 134 may drive firmware to control the overall operations of the memory system 110. The firmware may be referred to as flash translation layer (FTL).

The processor 134 of the controller 130 may include a management unit (not illustrated) for performing a bad management operation of the memory device 150. The management unit may perform a bad block management operation of checking a bad block, in which a program fail occurs due to the characteristic of a NAND flash memory during a program operation, among the plurality of memory blocks 152 to 156 included in the memory device 150. The management unit may write the program-failed data of the bad block to a new memory block. In the memory device 150 having a 3D stack structure, the bad block management operation may reduce the use efficiency of the memory device 150 and the reliability of the memory system 110. Thus, the bad block management operation needs to be performed with more reliability.

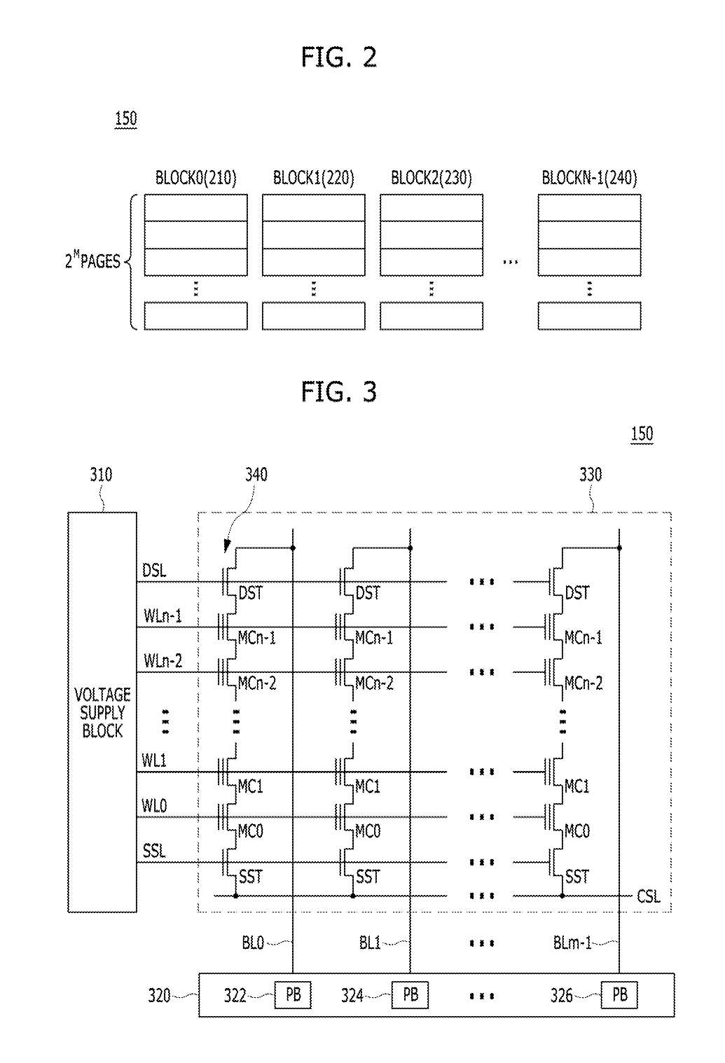

FIG. 2 is a schematic diagram illustrating the memory device 150.

Referring to FIG. 2, the memory device 150 may include a plurality of memory blocks 0 to N−1, and each of the blocks 0 to N−1 may include a plurality of pages, for example, 2^{M} pages, the number of which may vary according to circuit design. Memory cells included in the respective memory blocks 0 to N−1 may be one or more of a single level cell (SLC) storing 1-bit data, or a multi-level cell (MLC) storing 2- or more bit data. In an embodiment, the memory device 150 may include a plurality of triple level cells (TLC) each storing 3-bit data. In another embodiment, the memory device may include a plurality of quadruple level cells (QLC) each storing 4-bit level cell.

FIG. 3 is a circuit diagram illustrating an exemplary configuration of a memory cell array of a memory block in the memory device 150.

Referring to FIG. 3, a memory block 330 which may correspond to any of the plurality of memory blocks 152 to 156 included in the memory device 150 of the memory system 110 may include a plurality of cell strings 340 coupled to a plurality of corresponding bit lines BL0 to BLm−1. The cell string 340 of each column may include one or more drain select transistors DST and one or more source select transistors SST. Between the drain and source select transistors DST and SST, a plurality of memory cells MC0 to MCn−1 may be coupled in series. In an embodiment, each of the memory cell transistors MC0 to MCn−1 may be embodied by an MLC capable of storing data information of a plurality of bits. Each of the cell strings 340 may be electrically coupled to a corresponding bit line among the plurality of bit lines BL0 to BLm−1. For example, as illustrated in FIG. 3, the first cell string is coupled to the first bit line BL0, and the last cell string is coupled to the last bit line BLm−1.

Although FIG. 3 illustrates NAND flash memory cells, the invention is not limited in this way. It is noted that the memory cells may be NOR flash memory cells, or hybrid flash memory cells including two or more kinds of memory cells combined therein. Also, it is noted that the memory device 150 may be a flash memory device including a conductive floating gate as a charge storage layer or a charge trap flash (CTF) memory device including an insulation layer as a charge storage layer.

The memory device 150 may further include a voltage supply unit 310 which provides word line voltages including a program voltage, a read voltage and a pass voltage to supply to the word lines according to an operation mode. The voltage generation operation of the voltage supply unit 310 may be controlled by a control circuit (not illustrated). Under the control of the control circuit, the voltage supply unit 310 may select one of the memory blocks (or sectors) of the memory cell array, select one of the word lines of the selected memory block, and provide the word line voltages to the selected word line and the unselected word lines as may be needed.

The memory device 150 may include a read/write circuit 320 which is controlled by the control circuit. During a verification/normal read operation, the read/write circuit 320 may operate as a sense amplifier for reading data from the memory cell array. During a program operation, the read/write circuit 320 may operate as a write driver for driving bit lines according to data to be stored in the memory cell array. During a program operation, the read/write circuit 320 may receive from a buffer (not illustrated) data to be stored into the memory cell array, and drive bit lines according to the received data. The read/write circuit 320 may include a plurality of page buffers 322 to 326 respectively corresponding to columns (or bit lines) or column pairs (or bit line pairs), and each of the page buffers 322 to 326 may include a plurality of latches (not illustrated).

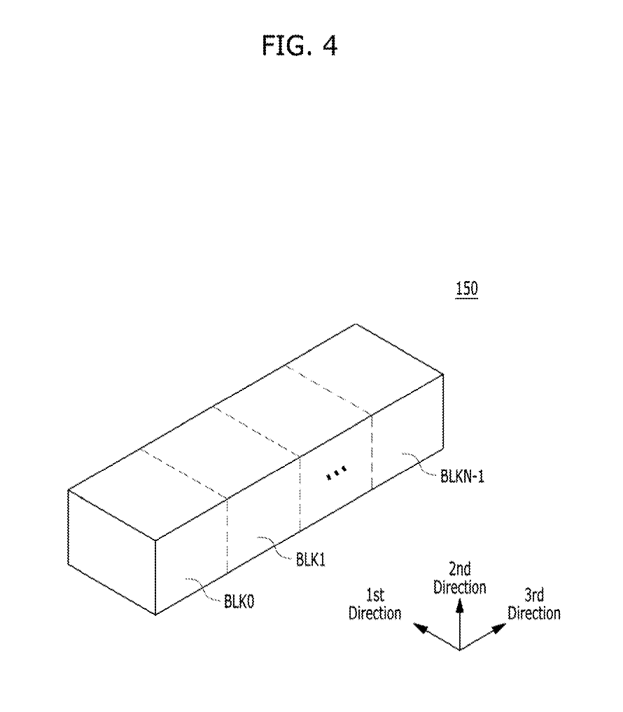

FIG. 4 is a schematic diagram illustrating an exemplary 3D structure of the memory device 150.

The memory device 150 may be embodied by a 2D or 3D memory device. Specifically, as illustrated in FIG. 4, the memory device 150 may be embodied by a nonvolatile memory device having a 3D stack structure. When the memory device 150 has a 3D structure, the memory device 150 may include a plurality of memory blocks BLK0 to BLKN−1 each having a 3D structure (or vertical structure).

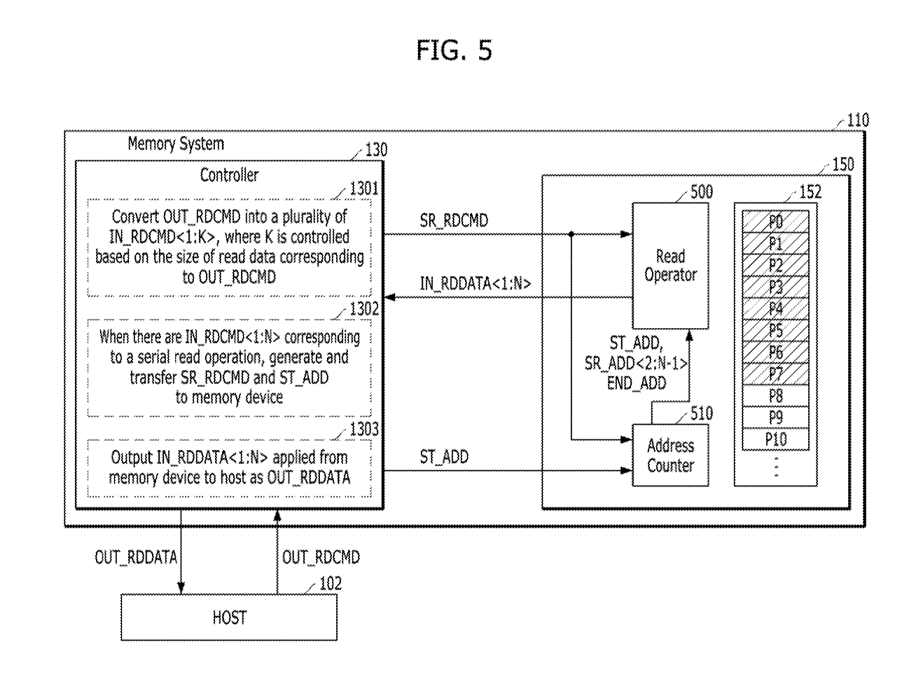

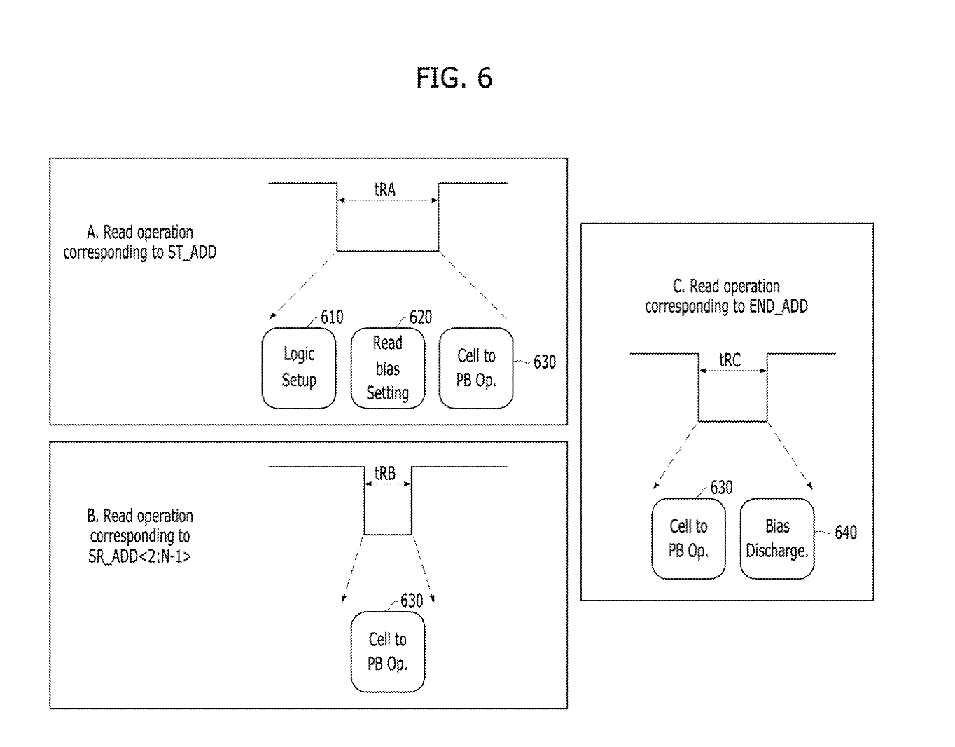

FIGS. 5 and 6 are simplified diagrams illustrating further aspects of the memory system 110 and an operation of the memory system 110.

Specifically, referring to FIG. 5, the memory device 150 may include a memory block 152, a read operator 500, and an address counter 510. Also, the memory block 152 may include a plurality of pages, P0, P1, P2, P3, P4, P5, P6, P7, P8, P9, P10, . . . for storing data on the basis of a page.

FIG. 5 shows a configuration where the memory system 110 includes only one memory device 150, however, it is noted that this is not more than one embodiment of the present invention and it should be apparent to those skilled in the art that more memory devices may be included in the memory system 110. Also, FIG. 5 shows that the memory device 150 includes one memory block 152, but this is not more than one embodiment of the present invention and it should be apparent to those skilled in the art that more memory blocks may be included in the memory system 110, as described with reference to FIG. 1. Also, the host interface 132, the processing unit 134, the ECC unit 138, the power management unit 140, the NAND flash controller unit 142, and the memory unit 144 which are shown to be included in the controller 130 in FIG. 1 are not shown in FIG. 5. It is noted that these are omitted from the FIG. 5 for the sake of convenience in description, and that they may be included in the controller 130.

In operation, when it is decided that an external read command OUT_RDCMD provided from the host 102 is for a serial read operation, the controller 130 may transfer a serial read command SR_RDCMD and a start address ST_ADD to the memory device 150, and then may output N data IN_RDDATA<1:N>, which are read from the memory device 150, to the host 102 as output data OUT_RDDATA, where N is a natural number greater than ‘3’.

The controller 130 may convert the external read command OUT_RDCMD into a plurality of internal read commands IN_RDCMD<1:K> each for performing a read operation on a single page. The number of the internal read commands IN_RDCMD<1:K> may depend on the size of a read data requested by the external read command OUT_RDCMD. In short, the internal read commands IN_RDCMD<1:K> are commands for reading the data on the basis of a page from the memory device 150, the number K of the internal read commands IN_RDCMD<1:K> may be controlled based on the size of the data corresponding to the external read command OUT_RDCMD. The unit of the read operation (e.g., a page) may vary according to a system design.

When the controller 130 detects N internal read commands IN_RDCMD<1:N> for a serial read operation, the controller 130 may generate a serial read command SR_RDCMD and a start address ST_ADD corresponding to the N internal read commands IN_RDCMD<1:N> and transfer the serial read command SR_RDCMD and the start address ST_ADD to the memory device 150. In other words, the controller 130 may detect N internal read commands IN_RDCMD<1:N> requesting a serial read operation among the internal read commands IN_RDCMD<1:K>, generate a serial read command SR_RDCMD and the start address ST_ADD corresponding to the detected N internal read commands IN_RDCMD<1:N>, and transfer the serial read command SR_RDCMD and the start address ST_ADD to the memory device 150.

The controller 130 may detect N internal read commands IN_RDCMD<1:N> for a serial read operation among the internal read commands IN_RDCMD<1:K> through the physical addresses that respectively correspond to the internal read commands IN_RDCMD<1:K>. When the physical addresses which respectively correspond to the N internal read commands IN_RDCMD<1:N> are consecutive, the controller 130 may determine that the N internal read commands IN_RDCMD<1:N> indicate a serial read operation.

The controller 130 may select as the start address ST_ADD a beginning one among the consecutive physical addresses respectively corresponding to the N internal read commands IN_RDCMD<1:N>.

Also, the controller 130 may generate the serial read command SR_RDCMD corresponding to the N internal read commands IN_RDCMD<1:N>, and may include the consecutive physical address numbers information of the N consecutive physical addresses into the serial read command SR_RDCMD.

The memory device 150 may consecutively read and output, as output data IN_RDDATA<1:N>, data from N pages of the N consecutive physical addresses in response to the serial read command SR_RDCMD, the start address ST_ADD and the consecutive physical address numbers information (i.e., a value of “N”).

The memory device 150 may read N data IN_RDDATA<1:N> by performing an operation which includes setting a read bias level, then performing an operation of reading data of the start address ST_ADD, which is provided along with the serial read command SR_RDCMD, and serial addresses SR_ADD<2:N−1> and an end address END_ADD, which are determined according to the start address ST_ADD and the consecutive physical address numbers information (i.e., a value of “N”) included in the serial read command SR_RDCMD, and then performing a discharge operation.

More specifically, the memory device 150 may read and output N data IN_RDDATA<1:N> to the controller 130 by counting the start address ST_ADD based on the information of the serial read command SR_RDCMD and generating serial addresses SR_ADD<2:N−1> and an end address END_ADD by selecting N pages among the pages P0, P1, P2, P3, P4, P5, P6, P7, P8, P9, P10, . . . based on the generated serial addresses SR_ADD<2:N−1> and end address END_ADD, performing an operation of setting the level of a read bias in response to the start address ST_ADD, performing a read operation, and performing a read operation in response to each of the serial addresses SR_ADD<2:N−1>, and perform a discharge operation after the read operations in response to the end address END_ADD.

For the operation of the memory device 150, the address counter 510 included in the memory device 150 may generate the serial addresses SR_ADD<2:N−1> and the end address END_ADD by counting the start address ST_ADD based on the information of the serial read command SR_RDCMD. In other words, as described above in the operation of the controller 130, the serial read command SR_RDCMD may include N physical addresses corresponding to the N internal read commands IN_RDCMD<1:N>, which is information on the value ‘N’. Therefore, the address counter 510 may be able to generate the serial addresses SR_ADD<2:N−1> and the end address END_ADD by checking the serial read command SR_RDCMD for the information on the value ‘N’ and counting the start address ST_ADD. For example, when it is assumed that ‘N’ is 8, the address counter 510 may be able to generate a total of six serial addresses SR_ADD<2:N−> and one end address END_ADD by performing an ascending or descending counting operation seven times from the start address ST_ADD.

Herein, when it is assumed that the controller 130 sets a physical address having the smallest value among N physical addresses of consecutive values corresponding to the N internal read commands IN_RDCMD<1:N> as the start address ST_ADD, the address counter 510 may generate the serial addresses SR_ADD<2:N−1> and the end address END_ADD through an ascending counting operation from the start address ST_ADD. Conversely, when it is assumed that the controller 130 sets a physical address having the smallest value among N physical addresses of consecutive values corresponding to the N internal read commands IN_RDCMD<1:N> as the start address ST_ADD, the address counter 510 may generate the serial addresses SR_ADD<2:N−1> and the end address END_ADD through a descending counting operation from the start address ST_ADD.

As described above, the serial addresses SR_ADD<2:N−1> and the end address END_ADD that are generated by the address counter 510 may be transferred to the read operator 500 along with the start address ST_ADD and used for the operation of selecting the N pages among the pages P0, P1, P2, P3, P4, P5, P6, P7, P8, P9, P10, . . . that are included in the memory device 150. The read operator 500 may perform the operation of setting the read bias level in response to the serial read command SR_RDCMD. After that, the read operator 500 may read N data IN_RDDATA<1:N> from N pages respectively indicated by the start address ST_ADD, serial addresses SR_ADD<2:N−1> and an end address END_ADD by using the read bias level. Then, the read operator 500 may perform a discharge operation. During the read operation, the read operator 500 may not perform the operation of setting the read bias level for the respective serial addresses SR_ADD<2:N−1> and an end address END_ADD. Once the read bias level is set, the N data IN_RDDATA<1:N> from N pages respectively indicated by the start address ST_ADD, serial addresses SR_ADD<2:N−1> and an end address END_ADD by using the single set read bias level.

To be specific, the read operator 500 may perform the operation of setting the level of the read bias in response to the serial read command SR_RDCMD and then read the first data IN_RDDATA<1> by selecting the first page according to the start address ST_ADD among the N pages based on the read bias, which is set. Subsequently, the read operator 500 may sequentially read the data IN_RDDATA<2:N−1> from the second data to the (N−1)^{th} data by using the read bias, which is set in the above, as it is and sequentially selecting the pages from the second page to the (N−1)^{th} page according to the serial addresses SR_ADD<2N−> among the N pages. Subsequently, the read operator 500 may read the N^{th} data IN_RDDATA<N> by using the read bias, which is set in the above, as it is and selecting the N^{th} page corresponding to the end address END_ADD among the N pages, and perform a discharge operation of discharging the level of the read bias.

For example, as illustrated in the drawing, it may be assumed that the N consecutive pages corresponding to the start address ST_ADD, the serial addresses SR_ADD<2:N−1>, and the end address END_ADD that are transferred from the address counter 510 ranges from a 0^{th} page to a seventh page P<0:7>. In this case, the read operator 500 may perform the operation of setting the read bias in response to the serial read command SR_RDCMD, may then read the first data IN_RDDATA<1> by using the set read bias, and may select the 0^{th} page P0 corresponding to the start address ST_ADD. Subsequently, the read operator 500 may sequentially read the second to seventh data IN_RDDATA<2:7> by using the set read bias and sequentially selecting the first to sixth pages P<1:6> according to the serial addresses SR_ADD<2:6>. Subsequently, the read operator 500 may read the eighth data IN_RDDATA<8> by using the set read bias selecting the seventh page P7 corresponding to the end address END_ADD, and performing a discharge operation of discharging the read bias level.

As described above, when data are read from N consecutive pages corresponding to the start address ST_ADD, the serial addresses SR_ADD<2:N−1>, and the end address END_ADD that are transferred from the address counter 510, the read operator 500 may set the read bias before a read operation for the first page corresponding to the start address ST_ADD, and then perform a read operation for all the pages, which are first to N^{th} pages, by using the above-set read bias, and discharge the read bias at a moment when the read operation for the N^{th} page is finished. Therefore, the operation of setting and discharging the read bias may be minimized during a reading operation of reading data of consecutive physical addresses.

Referring to FIG. 6, it may be seen that the time tRA taken for performing the read operation (denoted with A) corresponding to the start address ST_ADD, the time tRB taken for performing the read operation corresponding to the serial addresses SR_ADD<2:N−1> (denoted with B), and the time tRC taken for performing the read operation corresponding to the end address END_ADD (denoted with C) may be different in the read operator 500.

For Example, when the read operation corresponding to the start address ST_ADD is performed by the read operator 500 (denoted as “A. Read operation with the start address ST_ADD” in FIG. 6), the operations of setting the read bias level (denoted with reference 610 and 620 in FIG. 6) are performed first and then the read operation is performed (denoted with reference 630 in FIG. 6). Therefore, the read operation corresponding to the start address ST_ADD may take a relatively long time (tRA).

When the read operation with the serial addresses SR_ADD<2:N−1> is performed by the read operator 500 (denoted as “B. Read operation with the serial addresses SR_ADD<2:N−1>” in FIG. 6), the read operation may be performed (denoted with reference 630 in FIG. 6) by using the above-set read bias as it is. Therefore, any other operations may not have to be performed except the read operation (see 630). Therefore, the read operation with the serial addresses SR_ADD<2:N−1> may take a relatively short time (tRB) compared to the tRA

When the read operation corresponding to the end address END_ADD is performed in the read operator 500 (denoted as “C. Read operation with the end address END_ADD” in FIG. 6), the read operation may be performed (denoted with reference 630 in FIG. 6) by using the above-set read bias as it is and then the discharge operation of discharging the read bias (denoted with reference 640 in FIG. 6) may be performed. Therefore, the read operation corresponding to the end address END_ADD may take a relatively intermediate-level time (tRC).

The operations of setting the read bias level (see 610 and 620) require relatively high power consumption. Therefore, relatively significantly more power is consumed when the read operation corresponding to the start address ST_ADD is performed by the read operator 500, than when the read operation corresponding to the serial addresses SR_ADD<2:N−1> is performed by the read operator 500 or when the read operation corresponding to the end address END_ADD is performed by the read operator 500.

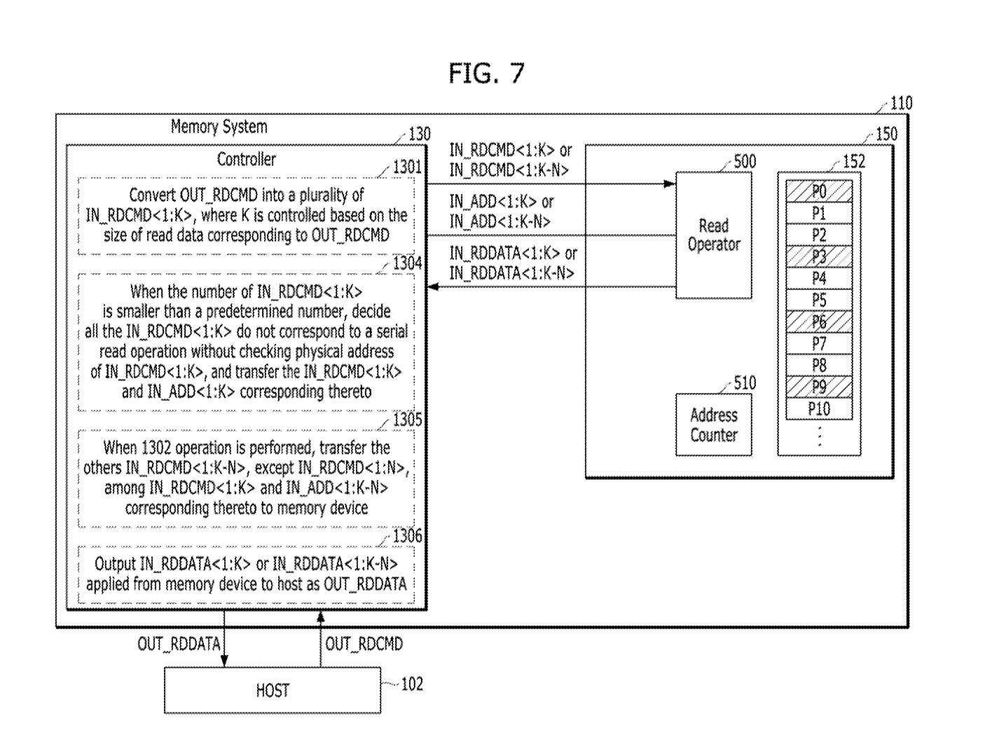

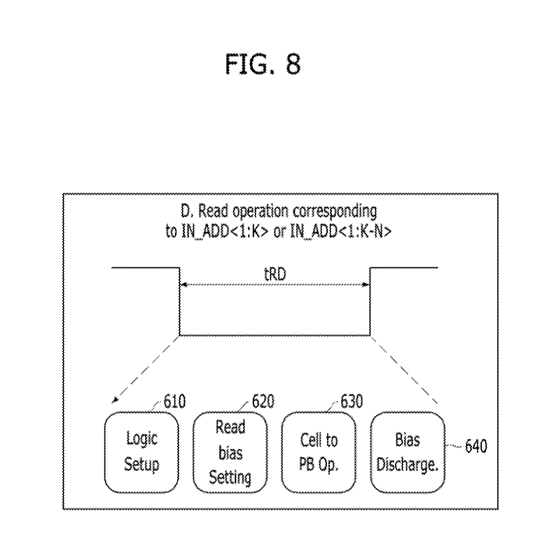

FIGS. 7 and 8 are block diagrams illustrating an additional operation performed by the memory system shown in FIG. 5.

Referring to FIG. 7, it may be seen that all the constituent elements of the memory system 110 shown in FIG. 7 are those already described above with reference to FIG. 5.

In short, what is described with reference to FIGS. 7 and 8 are an additional operation of the memory system 110. The description herein mainly focuses on the operational differences as compared with what was described above with reference to FIGS. 5 and 6.

First of all, the controller 130 may convert the external read command OUT_RDCMD applied from the host 102 into a plurality of internal read commands IN_RDCMD<1:K> for performing a read operation on the basis of a page (see 1301).

Herein, when the number of the internal read commands IN_RDCMD<1:K> is smaller than a predetermined number, all the internal read commands IN_RDCMD<1:K> do not correspond to a serial read operation, which is described above with reference to FIG. 5.

In other words, when the number of the internal read commands IN_RDCMD<1:K> is smaller than the predetermined number, the controller 130 may not perform an operation of checking the physical address of each of the internal read commands IN_RDCMD<1:K> but may decide that all the internal read commands IN_RDCMD<1:K> do not correspond to a serial read operation and transfer all the internal read commands IN_RDCMD<1:K> and physical addresses IN_ADD<1:K> which respectively correspond to the internal read commands IN_RDCMD<1:K> to the memory device 150.

Also, when the operation 1302 of checking the information of the internal read commands IN_RDCMD<1:K> in the controller 130, which is described with reference to FIG. 5, reveals that there are N internal read commands IN_RDCMD<1:N> corresponding to a serial read operation, the operation of generating a serial read command SR_RDCMD and a start address ST_ADD corresponding to the N internal read commands IN_RDCMD<1:N> and transferring the generated serial read command SR_RDCMD and the generated start address ST_ADD to the memory device 150. Herein, when K is greater than N, it may mean that there may be internal read commands IN_RDCMD<1:K−N> that correspond to internal read commands whose physical addresses are not consecutive among the internal read commands IN_RDCMD<1:K>. In short, there may be K−N internal read commands IN_RDCMD<1:K−N> which are the other internal read commands, except the N internal read commands IN_RDCMD<1:N> corresponding to a serial read operation, among the internal read commands IN_RDCMD<1:K>. In this case, the controller 130 may transfer the K−N internal read commands IN_RDCMD<1:K−N> and K−N physical addresses corresponding to the K−N internal read commands IN_RDCMD<1:K−N> to the memory device 150 (see 1305).

Herein, the internal read commands IN_RDCMD<1:K> or IN_RDCMD<1:N−K> that do not correspond to a serial read operation may be referred to as ‘random internal read commands’ that do not have consecutive physical addresses. Also, the physical addresses IN_ADD<1:K> or IN_ADD<K−N> corresponding to the random internal read commands may be referred to as ‘random physical addressess’.

When the random internal read commands IN_RDCMD<1:K> or IN_RDCMD<1:N−K> and the random physical addresses IN_ADD<1:K> or IN_ADD<K−N> are transferred to the memory device 150 as they are, the address counter 510 in the inside of the memory device 150 may not perform any operation. Instead, the read operator 500 in the inside of the memory device 150 may perform all the operations related to a read operation.

Herein, the fact that the read operator 500 performs all the operations related to a read operation means that the read operator 500 performs a read operation of a general memory device. In short, as illustrated in FIG. 8, the read operator 500 may perform all the operations of setting the read bias level in response to each of the random internal read commands IN_RDCMD<1:K> or IN_RDCMD<1:N−K> (see 610 and 620), reading data from pages respectively corresponding to the random physical addresses IN_ADD<1:K> or IN_ADD<K−N>> (see 630), and discharging the read bias (see 640).

Therefore, when all the read operations corresponding to the random internal read commands IN_RDCMD<1:K> or IN_RDCMD<1:N−K> are performed, it may take a longer time tRD than the time tRA, tRB or tRC taken for the read operation illustrated in FIG. 6.

Also, since the read operator 500 performs all the operations related to a read operation means that whenever the read operator 500 performs a read operation, the operations of setting the read bias level (see 610 and 620) and discharging the read bias (see 640) are all performed. Herein, since the number of the random internal read commands IN_RDCMD<1:K> or IN_RDCMD<1:N−K> is K or K−N, the operations illustrated in FIG. 8 may have to be repeatedly performed K or K−N times.

As a result of performing all the operations related to a read operation corresponding to the random internal read commands IN_RDCMD<1:K> or IN_RDCMD<1:N−K> in the read operator 500, the read operator 500 may output random data IN_RDDATA<1:K> or IN_RDDATA<1:K−N> to the controller 130, The controller 130 then may output the random data IN_RDDATA<1:K> or IN_RDDATA<1:K−N> to the host 102 (see 1305).

For example, as illustrated in FIG. 7, it may be assumed that a total of four random internal read commands IN_RDCMD<1:K> or IN_RDCMD<1:N−K> are transferred from the controller 130 and the random physical addresses IN_ADD<1:K> or IN_ADD<K−N> corresponding to the four random internal read commands IN_RDCMD<1:K> or IN_RDCMD<1:N−K> indicate 0^{th} page P0, a third page P3, a sixth page P6, and a ninth page P9. In this case, the read operator 500 may perform the operations of setting the read bias level (see 610 and 620) in response to the first random internal read command IN_RDCMD<1>, reading a first random data IN_RDDATA<1> by detecting the 0^{th} page P0 corresponding to the first random physical address IN_ADD<1> (see 630), and discharging the read bias (see 640).

Subsequently, the read operator 500 may perform the operations of setting the read bias level (see 610 and 620) in response to the second random internal read command IN_RDCMD<2>, reading a second random data IN_RDDATA<2> by detecting the third page P3 corresponding to the second random physical address IN_ADD<2> (see 630), and discharging the read bias (see 640).

Subsequently, the read operator 500 may perform the operations of setting the read bias level (see 610 and 620) in response to the third random internal read command IN_RDCMD<3>, reading a third random data IN_RDDATA<3> by detecting the sixth page P6 corresponding to the third random physical address IN_ADD<3> (see 630), and discharging the read bias (see 640).

Subsequently, the read operator 500 may perform the operations of setting the read bias level (see 610 and 620) in response to the fourth random internal read command IN_RDCMD<4>, reading a fourth random data IN_RDDATA<4> by detecting the ninth page P9 corresponding to the fourth random physical address IN_ADD<4> (see 630), and discharging the read bias (see 640).

As described above, when the read operator 500 reads data corresponding to the random internal read commands IN_RDCMD<1:K> or IN_RDCMD<1:N−K> and the random physical addresses IN_ADD<1:K> or IN_ADD<−K−N>, the read operator 500 may have to repeatedly perform the operations of setting the read bias level (see 610 and 620) and discharging the read bias (see 640) every time when one read operation is performed (see 630). This quite disagrees with the characterizing operation of the present invention described above with reference to FIGS. 5 and 6 is minimizing the operations of setting the read bias and discharging the read bias.

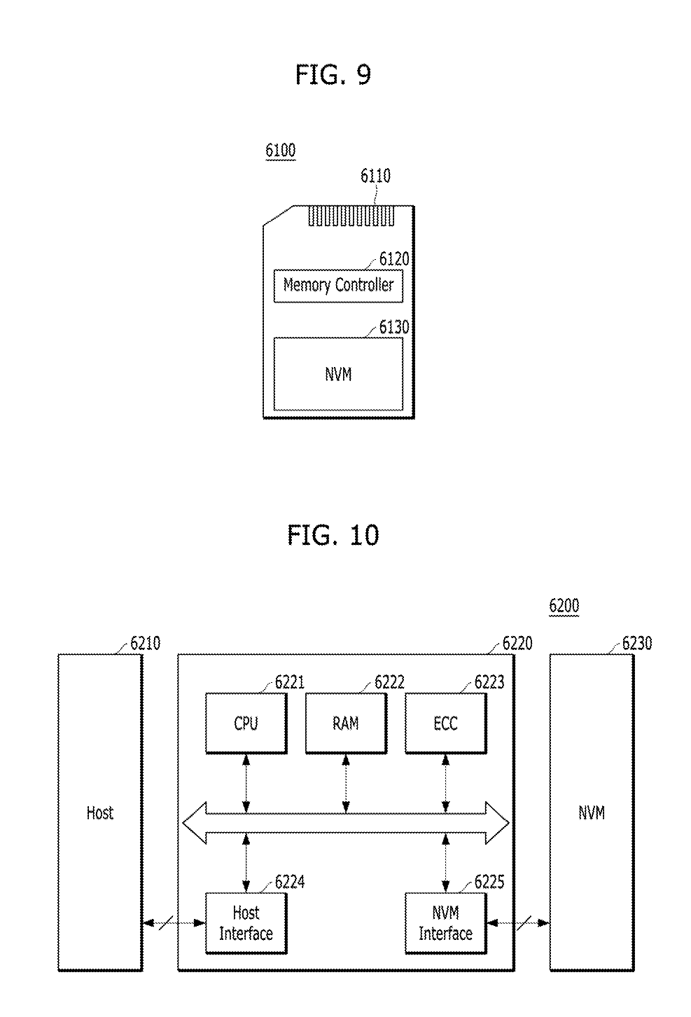

FIGS. 9 to 17 are diagrams schematically illustrating application examples of the data processing system of FIG. 1.

FIG. 9 is a diagram schematically illustrating another example of the data processing system including the memory system in accordance with the present embodiment. FIG. 9 schematically illustrates a memory card system to which the memory system in accordance with the present embodiment is applied.

Referring to FIG. 9, the memory card system 6100 may include a memory controller 6120, a memory device 6130 and a connector 6110.

More specifically, the memory controller 6120 may be connected to the memory device 6130 embodied by a nonvolatile memory, and configured to access the memory device 6130. For example, the memory controller 6120 may be configured to control read, write, erase and background operations of the memory device 6130. The memory controller 6120 may be configured to provide an interface between the memory device 6130 and a host, and drive firmware for controlling the memory device 6130. That is, the memory controller 6120 may correspond to the controller 130 of the memory system 110 described with reference to FIGS. 1 and 5, and the memory device 6130 may correspond to the memory device 150 of the memory system 110 described with reference to FIGS. 1 and 5.

Thus, the memory controller 6120 may include a RAM, a processing unit, a host interface, a memory interface and an error correction unit. The memory controller 130 may further include the elements shown in FIG. 5.

The memory controller 6120 may communicate with an external device, for example, the host 102 of FIG. 1 through the connector 6110. For example, as described with reference to FIG. 1, the memory controller 6120 may be configured to communicate with an external device through one or more of various communication protocols such as universal serial bus (USB), multimedia card (MMC), embedded MMC (eMMC), peripheral component interconnection (PCI), PCI express (PCIe), Advanced Technology Attachment (ATA), Serial-ATA, Parallel-ATA, small computer system interface (SCSI), enhanced small disk interface (EDSI), Integrated Drive Electronics (IDE), Firewire, universal flash storage (UFS), WIFI and Bluetooth. Thus, the memory system and the data processing system in accordance with the present embodiment may be applied to wired/wireless electronic devices or particularly mobile electronic devices.

The memory device 6130 may be implemented by a nonvolatile memory. For example, the memory device 6130 may be implemented by various nonvolatile memory devices such as an erasable and programmable ROM (EPROM), an electrically erasable and programmable ROM (EEPROM), a NAND flash memory, a NOR flash memory, a phase-change RAM (PRAM), a resistive RAM (ReRAM), a ferroelectric RAM (FRAM) and a spin torque transfer magnetic RAM (STT-RAM). The memory device 6130 may include a plurality of dies as in the memory device 150 of FIG. 5.

The memory controller 6120 and the memory device 6130 may be integrated into a single semiconductor device. For example, the memory controller 6120 and the memory device 6130 may construct a solid state driver (SSD) by being integrated into a single semiconductor device. Also, the memory controller 6120 and the memory device 6130 may construct a memory card such as a PC card (PCMCIA: Personal Computer Memory Card International Association), a compact flash (CF) card, a smart media card (e.g., SM and SMC), a memory stick, a multimedia card (e.g., MMC, RS-MMC, MMCmicro and eMMC), an SD card (e.g., SD, miniSD, microSD and SDHC) and a universal flash storage (UFS).

FIG. 10 is a diagram schematically illustrating another example of the data processing system including the memory system in accordance with the present embodiment.

Referring to FIG. 10, the data processing system 6200 may include a memory device 6230 having one or more nonvolatile memories and a memory controller 6220 for controlling the memory device 6230. The data processing system 6200 illustrated in FIG. 10 may serve as a storage medium such as a memory card (CF, SD, micro-SD or the like) or USB device, as described with reference to FIG. 1. The memory device 6230 may correspond to the memory device 150 in the memory system 110 illustrated in FIGS. 1 and 5, and the memory controller 6220 may correspond to the controller 130 in the memory system 110 illustrated in FIGS. 1 and 5.

The memory controller 6220 may control a read, write or erase operation on the memory device 6230 in response to a request of the host 6210, and the memory controller 6220 may include one or more CPUs 6221, a buffer memory such as RAM 62222, an ECC circuit 6223, a host interface 6224 and a memory interface such as an NVM interface 6225.

The CPU 6221 may control overall operations on the memory device 6230, for example, read, write, file system management and bad page management operations. The RAM 6222 may be operated according to control of the CPU 6221, and used as a work memory, buffer memory or cache memory. When the RAM 6222 is used as a work memory, data processed by the CPU 6221 may be temporarily stored in the RAM 6222. When the RAM 6222 is used as a buffer memory, the RAM 6222 may be used for buffering data transmitted to the memory device 6230 from the host 6210 or transmitted to the host 6210 from the memory device 6230. When the RAM 6222 is used as a cache memory, the RAM 6222 may assist the low-speed memory device 6230 to operate at high speed.

The ECC circuit 6223 may correspond to the ECC unit 138 of the controller 130 illustrated in FIG. 1. As described with reference to FIG. 1, the ECC circuit 6223 may generate an ECC (Error Correction Code) for correcting a fail bit or error bit of data provided from the memory device 6230. The ECC circuit 6223 may perform error correction encoding on data provided to the memory device 6230, thereby forming data with a parity bit. The parity bit may be stored in the memory device 6230. The ECC circuit 6223 may perform error correction decoding on data outputted from the memory device 6230. At this time, the ECC circuit 6223 may correct an error using the parity bit. For example, as described with reference to FIG. 1, the ECC circuit 6223 may correct: an error using the LDPC code, BCH code, turbo code, Reed-Solomon code, convolution code, RSC or coded modulation such as TCM or BCM.

The memory controller 6220 may transmit/receive data to/from the host 6210 through the host interface 6224, and transmit/receive data to/from the memory device 6230 through the NVM interface 6225. The host interface 6224 may be connected to the host 6210 through a PATA bus, SATA bus, SCSI, USB, PCIe or NAND interface. The memory controller 6220 may have a wireless communication function with a mobile communication protocol such as WiR or Long Term Evolution (LTE). The memory controller 6220 may be connected to an external device, for example, the host 6210 or another external device, and then transmit/receive data to/from the external device. In particular, as the memory controller 6220 is configured to communicate with the external device through one or more of various communication protocols, the memory system and the data processing system in accordance with the present embodiment may be applied to wired/wireless electronic devices or particularly a mobile electronic device.

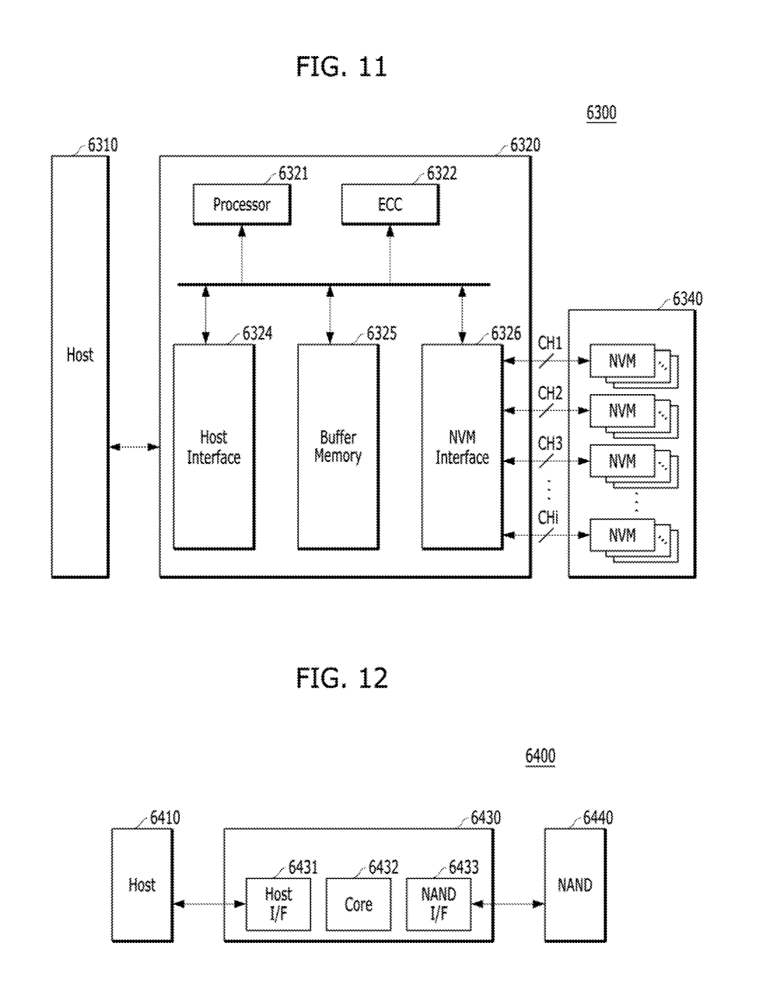

FIG. 11 is a diagram schematically illustrating another example of the data processing system including the memory system in accordance with the present embodiment. FIG. 11 schematically illustrates an SSD to which the memory system in accordance with the present embodiment is applied.

Referring to FIG. 11, the SSD 6300 may include a controller 6320 and a memory device 6340 including a plurality of nonvolatile memories. The controller 6320 may correspond to the controller 130 in the memory system 110 described in FIGS. 1 to 9, and the memory device 6340 may correspond to the memory device 150 in the memory system described in FIGS. 1 to 9.

More specifically, the controller 6320 may be connected to the memory device 6340 through a plurality of channels CH1 to CHi. The controller 6320 may include one or more processors 6321, a buffer memory 6325, an ECC circuit 6322, a host interface 6324 and a memory interface, for example, a nonvolatile memory interface 6326.

The buffer memory 6325 may temporarily store data provided from the host 6310 or data provided from a plurality of flash memories NVM included in the memory device 6340, or temporarily store meta data of the plurality of flash memories NVM, for example, map data including a mapping table. The buffer memory 6325 may be embodied by volatile memories such as DRAM, SDRAM, DDR SDRAM, LPDDR SDRAM and GRAM or nonvolatile memories such as FRAM, ReRAM, STT-MRAM and PRAM. For convenience of description, FIG. 10 illustrates that the buffer memory 6325 exists in the controller 6320. However, the buffer memory 6325 may exist outside the controller 6320.

The ECC circuit 6322 may calculate an ECC value of data to be programmed to the memory device 6340 during a program operation, perform an error correction operation on data read from the memory device 6340 based on the ECC value during a read operation, and perform an error correction operation on data recovered from the memory device 6340 during a failed data recovery operation.

The host interface 6324 may provide an interface function with an external device, for example, the host 6310, and the nonvolatile memory interface 6326 may provide an interface function with the memory device 6340 connected through the plurality of channels.

Furthermore, a plurality of SSDs 6300 to which the memory system 110 described in FIGS. 1 to 9 is applied may be provided to embody a data processing system, for example, RAID (Redundant Array of Independent Disks) system. At this time, the RAID system may include the plurality of SSDs 6300 and a RAID controller for controlling the plurality of SSDs 6300. When the RAID controller performs a program operation in response to a write command provided from the host 6310, the RAID controller may select one or more memory systems or SSDs 6300 according to a plurality of RAID levels, that is, RAID level information of the write command provided from the host 6310 in the SSDs 6300, and output data corresponding to the write command to the selected SSDs 6300. Furthermore, when the RAID controller performs a read command in response to a read command provided from the host 6310, the RAID controller may select one or more memory systems or SSDs 6300 according to a plurality of RAID levels, that is, RAID level information of the read command provided from the host 6310 in the SSDs 6300, and provide data read from the selected SSDs 6300 to the host 6310.

FIG. 12 is a diagram schematically illustrating another example of the data processing system including the memory system in accordance with the present embodiment. FIG. 12 schematically illustrates an embedded Multi-Media Card (eMMC) to which the memory system in accordance with the present embodiment is applied.

Referring to FIG. 12, the eMMC 6400 may include a controller 6430 and a memory device 6440 embodied by one or more NAND flash memories. The controller 6430 may correspond to the controller 130 in the memory system 110 described in FIGS. 1 to 9, and the memory device 6440 may correspond to the memory device 150 in the memory system 110 described in FIGS. 1 to 9.

More specifically, the controller 6430 may be connected to the memory device 6440 through a plurality of channels. The controller 6430 may include one or more cores 6432, a host interface 6431 and a memory interface, for example, a NAND interface 6433.

The core 6432 may control overall operations of the eMMC 6400, the host interface 6431 may provide an interface function between the controller 6430 and the host 6410, and the NAND interface 6433 may provide an interface function between the memory device 6440 and the controller 6430. For example, the host interface 6431 may serve as a parallel interface, for example, MMC interface as described with reference to FIG. 1. Furthermore, the host interface 6431 may serve as a serial interface, for example, UHS ((Ultra High Speed)-I/UHS-II) interface.

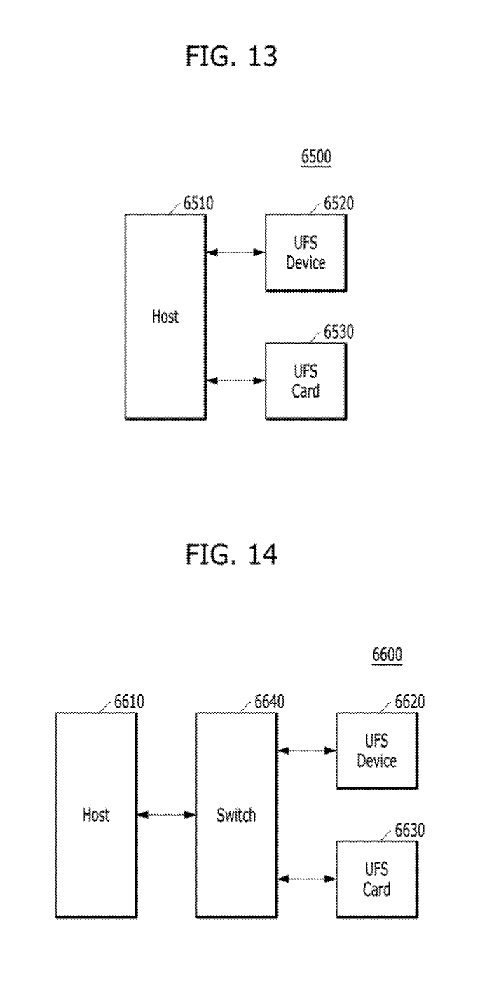

FIGS. 13 to 16 are diagrams schematically illustrating other examples of the data processing system including the memory system in accordance with the present embodiment. FIGS. 13 to 16 schematically illustrate UFS (Universal Flash Storage) systems to which the memory system in accordance with the present embodiment is applied.

Referring to FIGS. 13 to 16, the UFS systems 6500, 6600, 6700 and 6800 may include hosts 6510, 6610, 6710 and 6810, UFS devices 6520, 6620, 6720 and 6820 and UFS cards 6530, 6630, 6730 and 6830, respectively. The hosts 6510, 6610, 6710 and 6810 may serve as application processors of wired/wireless electronic devices or particularly mobile electronic devices, the UFS devices 6520, 6620, 6720 and 6820 may serve as embedded UFS devices, and the UFS cards 6530, 6630, 6730 and 6830 may serve as external embedded UFS devices or removable UFS cards.

The hosts 6510, 6610, 6710 and 6810, the UFS devices 6520, 6620, 6720 and 6820 and the UFS cards 6530, 6630, 6730 and 6830 in the respective UFS systems 6500, 6600, 6700 and 6800 may communicate with external devices, for example, wired/wireless electronic devices or particularly mobile electronic devices through UFS protocols, and the UFS devices 6520, 6620, 6720 and 6820 and the UFS cards 6530, 6630, 6730 and 6830 may be embodied by the memory system 110 illustrated in FIGS. 1 to 9. For example, in the UFS systems 6500, 6600, 6700 and 6800, the UFS devices 6520, 6620, 6720 and 6820 may be embodied in the form of the data processing system 6200, the SSD 6300 or the eMMC 6400 described with reference to FIGS. 10 to 12, and the UFS cards 6530, 6630, 6730 and 6830 may be embodied in the form of the memory card system 6100 described with reference to FIG. 9.

Furthermore, in the UFS systems 6500, 6600, 6700 and 6800, the hosts 6510, 6610, 6710 and 6810, the UFS devices 6520, 6620, 6720 and 6820 and the UFS cards 6530, 6630, 6730 and 6830 may communicate with each other through an UFS interface, for example, MIPI M-PHY and MIPI UniPro (Unified Protocol) in MIPI (Mobile Industry Processor Interface). Furthermore, the UFS devices 6520, 6620, 6720 and 6820 and the UFS cards 6530, 6630, 6730 and 6830 may communicate with each other through various protocols other than the UFS protocol, for example, UFDs, MMC, SD, mini-SD, and micro-SD.

In the UFS system 6500 illustrated in FIG. 13, each of the host 6510, the UFS device 6520 and the UFS card 6530 may include UniPro. The host 6510 may perform a switching operation in order to communicate with the UFS device 6520 and the UFS card 6530. In particular, the host 6510 may communicate with the UFS device 6520 or the UFS card 6530 through: link layer switching, for example, L3 switching at the UniPro. At this time, the UFS device 6520 and the UFS card 6530 may communicate with each other through link layer switching at the UniPro of the host 6510. In the present embodiment, the configuration in which one UFS device 6520 and one UFS card 6530 are connected to the host 6510 has been exemplified for convenience of description. However, a plurality of UFS devices and UFS cards may be connected in parallel or in the form of a star to the host 6410, and a plurality of UFS cards may be connected in parallel or in the form of a star to the UFS device 6520 or connected in series or in the form of a chain to the UFS device 6520.

In the UFS system 6600 illustrated in FIG. 14, each of the host 6610, the UFS device 6620 and the UFS card 6630 may include UniPro, and the host 6610 may communicate with the UFS device 6620 or the UFS card 6630 through a switching module 6640 performing a switching operation, for example, through the switching module 6640 which performs link layer switching at the UniPro, for example, L3 switching. The UFS device 6620 and the UFS card 6630 may communicate with each other through link layer switching of the switching module 6640 at UniPro. In the present embodiment, the configuration in which one UFS device 6620 and one UFS card 6630 are connected to the switching module 6640 has been exemplified for convenience of description. However, a plurality of UFS devices and UFS cards may be connected in parallel or in the form of a star to the switching module 6640, and a plurality of UFS cards may be connected in series or in the form of a chain to the UFS device 6620.

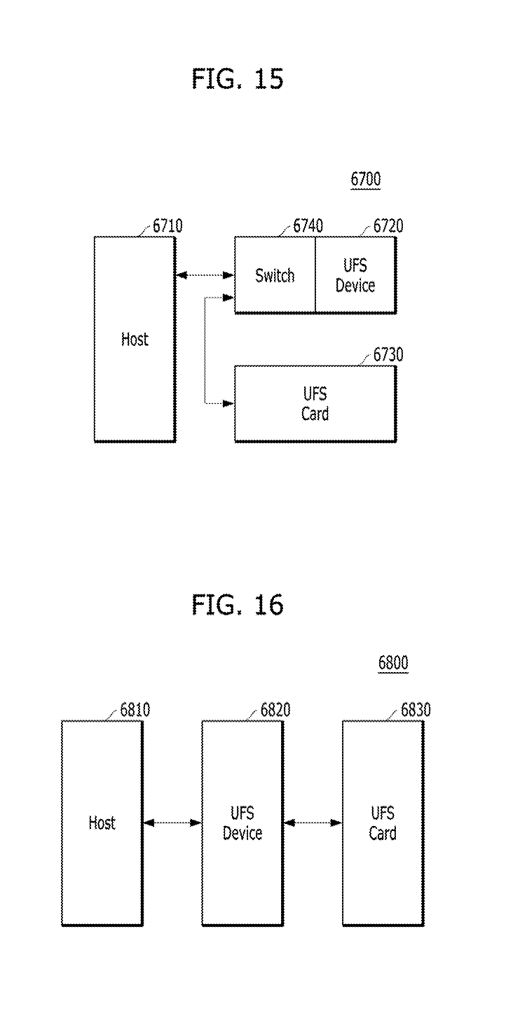

In the UFS system 6700 illustrated in FIG. 15, each of the host 6710, the UFS device 6720 and the UFS card 6730 may include UniPro, and the host 6710 may communicate with the UFS device 6720 or the UFS card 6730 through a switching module 6740 performing a switching operation, for example, through the switching module 6740 which performs link layer switching at the UniPro, for example, L3 switching. At this time, the UFS device 6720 and the UFS card 6730 may communicate with each other through link layer switching of the switching module 6740 at the UniPro, and the switching module 6740 may be integrated as one module with the UFS device 6720 inside or outside the UFS device 6720. In the present embodiment, the configuration in which one UFS device 6720 and one UFS card 6730 are connected to the switching module 6740 has been exemplified for convenience of description. However, a plurality of modules each including the switching module 6740 and the UFS device 6720 may be connected in parallel or in the form of a star to the host 6710 or connected in series or in the form of a chain to each other. Furthermore, a plurality of UFS cards may be connected in parallel or in the form of a star to the UFS device 6720.

In the UFS system 6800 illustrated in FIG. 16, each of the host 6810, the UFS device 6820 and the UFS card 6830 may include M-PHY and UniPro. The UFS device 6820 may perform a switching operation in order to communicate with the host 6810 and the UFS card 6830. In particular, the UFS device 6820 may communicate with the host 6810 or the UFS card 6830 through a switching operation between the M-PHY and UniPro module for communication with the host 6810 and the M-PHY and UniPro module for communication with the UFS card 6830, for example, through a target ID (Identifier) switching operation. At this time, the host 6810 and the UFS card 6830 may communicate with each other through target ID switching between the M-PHY and UniPro modules of the UFS device 6820. In the present embodiment, the configuration in which one UFS device 6820 is connected to the host 6810 and one UFS card 6830 is connected to the UFS device 6820 has been exemplified for convenience of description. However, a plurality of UFS devices may be connected in parallel or in the form of a star to the host 6810, or connected in series or in the form of a chain to the host 6810, and a plurality of UFS cards may be connected in parallel or in the form of a star to the UFS device 6820, or connected in series or in the form of a chain to the UFS device 6820.

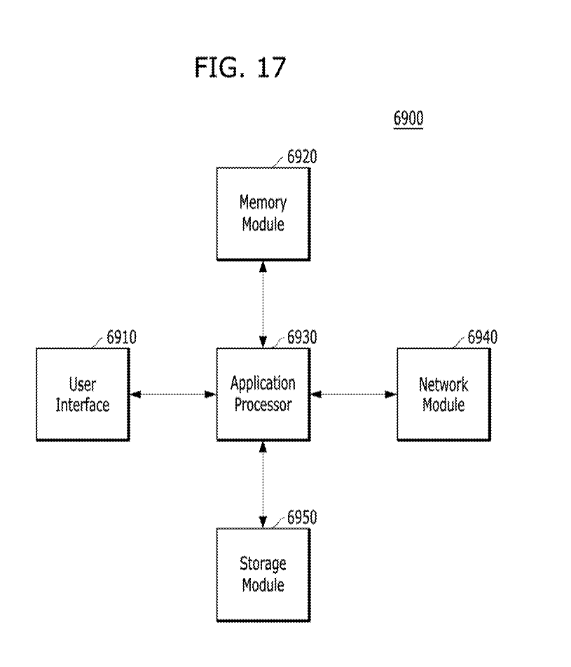

FIG. 17 is a diagram schematically illustrating another example of the data processing system including the memory system in accordance with an embodiment. FIG. 17 is a diagram schematically illustrating a user system to which the memory system in accordance with the present embodiment is applied.

Referring to FIG. 17, the user system 6900 may include an application processor 6930, a memory module 6920, a network module 6940, a storage module 6950 and a user interface 6910.

More specifically, the application processor 6930 may drive components included in the user system 6900, for example, an OS, and include controllers, interfaces and a graphic engine which control the components included in the user system 6900. The application processor 6930 may be provided as System-on-Chip (SoC).

The memory module 6920 may be used as a main memory, work memory, buffer memory or cache memory of the user system 6900. The memory module 6920 may include a volatile RAM such as DRAM, SDRAM, DDR SDRAM, DDR2 SDRAM, DDR3 SDRAM, LPDDR SDARM, LPDDR3 SDRAM or LPDDR3 SDRAM or a nonvolatile RAM such as PRAM, ReRAM, MRAM or FRAM. For example, the application processor 6930 and the memory module 6920 may be packaged and mounted, based on POP (Package on Package).

The network module 6940 may communicate with external devices. For example, the network module 6940 may not only support wired communication, but also support various wireless communication protocols such as code division multiple access (CDMA), global system for mobile communication (GSM), wideband CDMA (WCDMA), CDMA-2000, time division multiple access (TDMA), long term evolution (LTE), worldwide interoperability for microwave access (Wimax), wireless local area network (WLAN), ultra-wideband (UWB), Bluetooth, wireless display (WI-DI), thereby communicating with wired/wireless electronic devices or particularly mobile electronic devices. Therefore, the memory system and the data processing system, in accordance with an embodiment of the present invention, can be applied to wired/wireless electronic devices. The network module 6940 may be included in the application processor 6930.

The storage module 6950 may store data, for example, data received from the application processor 6930, and then may transmit the stored data to the application processor 6930. The storage module 6950 may be embodied by a nonvolatile semiconductor memory device such as a phase-change RAM (PRAM), a magnetic RAM (MRAM), a resistive RAM (ReRAM), a NAND flash, NOR flash and 3D NAND flash, and provided as a removable storage medium such as a memory card or external drive of the user system 6900. The storage module 6950 may correspond to the memory system 110 described with reference to FIGS. 1 and 5. Furthermore, the storage module 6950 may be embodied as an SSD, eMMC and UFS as described above with reference to FIGS. 11 to 16.

The user interface 6910 may include interfaces for inputting data or commands to the application processor 6930 or outputting data to an external device. For example, the user interface 6910 may include user input interfaces such as a keyboard, a keypad, a button, a touch panel, a touch screen, a touch pad, a touch ball, a camera, a microphone, a gyroscope sensor, a vibration sensor and a piezoelectric element, and user output interfaces such as a liquid crystal display (LCD), an organic light emitting diode (OLED) display device, an active matrix OLED (AMOLED) display device, an LED, a speaker and a motor.

Furthermore, when the memory system 110 described in FIGS. 1 to 9 is applied to a mobile electronic device of the user system 6900, the application processor 6930 may control overall operations of the mobile electronic device, and the network module 6940 may serve as a communication module for controlling wired/wireless communication with an external device. The user interface 6910 may display data processed by the processor 6930 on a display/touch module of the mobile electronic device, or support a function of receiving data from the touch panel.

According to the embodiments of the present invention, when data for which a read operation is requested by a host are turned out to be stored in physically consecutive space in the inside of a memory system, a memory system may efficiently perform a read operation in a memory device by separately generating a serial command corresponding thereto and controlling the operation of the memory device. In this way, the time and power consumed for performing the read operation may be saved.

While the present invention has been described with respect to the specific embodiments, it will be apparent to those skilled in the art that various changes and modifications may be made without departing from the spirit and scope of the invention as defined in the following claims.

What is claimed is:

1. A memory system, comprising:
a memory device; and
a controller suitable for controlling the memory device to perform a serial read operation by providing a serial read command and a start physical address for the serial read command when an external read command includes a request for the serial read operation,
wherein the serial read command includes consecutive physical address numbers information,
wherein, in response to the serial read command, the memory device sets a read bias, reads data stored therein with the set read bias according to the start physical address and the consecutive physical address numbers information, and then discharges the read bias.

2. The memory system of claim 1,
wherein the controller further determines whether or not the external read command includes the request for the serial read operation by converting the external read command into a plurality of internal read commands each for indicating a read operation performed by a unit of a page, and by determining whether physical addresses corresponding to the internal read commands are consecutive, and
wherein a number of the internal read commands is greater than 3.

3. The memory system of claim 2, wherein, when the physical addresses corresponding to the internal read commands are determined as consecutive, the controller further selects as the start physical address a beginning one among the consecutive physical addresses.

4. The memory system of claim 3, wherein the consecutive physical address numbers information is information of a number of the consecutive physical addresses.

5. The memory system of claim 1, wherein the memory device includes:
an address counter suitable for generating subsequent serial addresses and an end physical address based on the start physical address and the consecutive physical address numbers information; and
a read operator suitable for setting a read bias level, reading data of the start physical address, the subsequent serial address and the end physical address of the memory device with the set read bias level, and then discharging the set read bias level.

6. A method for operating a memory system provided with a memory device and a controller, the method comprising:
controlling, by the controller, the memory device to perform the serial read operation by providing a serial read command and a start physical address for the serial read command, wherein the serial read command includes consecutive physical address numbers information when an external read command includes a request for a serial read operation;
setting, by the memory device, a read bias in response to the serial read command;
reading, by the memory device, data stored therein with the set read bias according to the start physical address and the consecutive physical address numbers information; and
discharging, by the memory device, the read bias.

7. The method of claim 6, further comprising determining whether or not the external read command includes the request for the serial read operation includes converting the external read command into a plurality of internal read commands each for indicating a read operation performed by a unit of a page, and determining physical addresses corresponding to the internal read commands are consecutive,
wherein a number of the internal read commands is greater than 3.

8. The method of claim 7, further comprising, by the controller when the physical addresses corresponding to the internal read commands are determined as consecutive, selecting as the start physical address a beginning one among the consecutive physical addresses.

9. The method of claim 8, wherein the consecutive physical address numbers information is information of a number of the consecutive physical addresses.

10. The method of claim 6, wherein the reading of the data includes:
generating subsequent serial addresses and an end physical address based on the start physical address and the consecutive physical address numbers information; and
reading data of the start physical address, the subsequent serial address and the end physical address of the memory device with the set read bias level.
